(19) United States
(12) Patent Application Publication
(10) Pub. No.: US 2021/0082961 A1
(43) Pub. Date: Mar. 18, 2021

(54) DISPLAY DEVICE AND ARRAY SUBSTRATE THEREOF

(71) Applicant: Wuhan China Star Optoelectronics Technology Co.,Ltd, Wuhan, Hubei (CN)

(72) Inventor: Yuebai HAN, Wuhan, Hubei (CN)

(21) Appl. No.: 16/076,252

(22) PCT Filed: May 22, 2018
(86) PCT No.: PCT/CN2018/087844

§ 371 Date: Aug. 7, 2018

(30) Foreign Application Priority Data
Mar. 29, 2018 (CN) 201810270322.6

(51) Int. Cl. H01L 27/12; G02F 1/1362; G02F 1/1333; G06F 3/041

(52) U.S. Cl. CPC H01L 27/124; G02F 1/13629; G02F 2202/104; G06F 3/0412; G02F 2201/40; G02F 1/13338

(57) ABSTRACT

The present invention teaches a display device and its array substrate. The array substrate includes pixel units arranged in an array, each including pixel electrode, TFT, touch electrode, scan line, and data line. The scan and data lines are configured along first and second directions, respectively. The scan lines and data lines cross each other. The pixel electrodes are connected to the scan and data lines through the TFTs. Each pixel unit also includes first and second metallic lines configured along the first and second directions, respectively. The first and second metallic lines are disposed in a same layer as the scan and data lines, respectively. Two neighboring first metallic lines along the first direction are connected by a second metallic line. The first metallic lines are connected to the second metallic line through first vias. The second metallic line is connected to a touch electrode through a second via.

### FIELD OF THE INVENTION

The present invention is generally related to the field of display technology, and more particularly to a display device and its array substrate.

### BACKGROUND OF THE INVENTION

Low temperature poly-silicon (UPS) panel is the mainstream product for flat panel displays due to tis high resolution, superior mobility, and low power consumption, and has been widely applied to mobile phones and tablet computers by manufacturers such as Apple, Samsung, Huawei, Xiomia, Meizu. LIPS array has a complex manufacturing process requiring multiple masks. Therefore, reducing the number of masks may effectively lower the manufacturing cost. Currently, an in-cell touch panel generally requires 13 masks. To reduce cost, manufacturers usually use M2 touch signal transmission and may achieve 9 masks. However, due to the high density of M2, the aperture ratio may be compromised.

### SUMMARY OF THE INVENTION

To resolve the above problems, the present invention teaches a display device and its array substrate that may enhance the aperture ratio of the display device, and reduce power consumption.

The present invention teaches an array substrate, which includes a number of pixel units arranged in an array. Each pixel unit includes a pixel electrode, a thin film transistor (TFT), a touch electrode, a scan line, and a data line. The scan lines are configured along a first direction. The data lines are configured along a second direction. The scan lines and data lines cross each other. The pixel electrodes are connected to the scan lines and the data lines through the TFTs. Each pixel unit further includes a first metallic line configured along the first direction and a second metallic line configured along the second direction. The first metallic lines are disposed in a same layer as the scan lines. The second metallic lines are disposed in a same layer as the data lines. Two neighboring first metallic lines along the first direction are connected by a second metallic line. The first metallic lines are connected to the second metallic lines through first vias. The second metallic lines are connected to touch electrodes through second vias.

Furthermore, the data lines cover sections of the first metallic lines along the first direction.

Furthermore, each first metallic line comprises a vertical section along the first direction and lateral sections extended from two ends of the vertical section along the second direction; the data lines cover the vertical sections; and the lateral sections are connected to the second metallic lines through the first vias.

Furthermore, the lateral sections are parallel to the scan lines.

Furthermore, the second metallic lines and the pixel electrodes are respectively disposed to the laterals sides of the data lines.

Furthermore, the second metallic lines are disposed in a display area of the array substrate.

Furthermore, the TFTs are top-gated TFTs.

Furthermore, each pixel unit comprises a substrate, a first buffer layer, a shading layer, a second buffer layer, a poly-silicon (poly-Si) layer, a gate insulation layer, a first metallic layer, a first interlayer dielectric (ILD) layer, a second metallic layer, a second ILD layer, a touch electrode, a third ILD layer, and a pixel electrode; the first metallic layer is for forming the first metallic lines and scan lines; and the second metallic layer is for forming the second metallic lines and data lines.

The present invention also teaches a display device, including one of the above described array substrates.

Each pixel unit includes a first metallic line configured along the first direction and second metallic line configured along the second direction. The first metallic lines are disposed in a same layer as the scan lines. The second metallic lines are disposed in a same layer as the data lines. Two neighboring first metallic lines along the first direction are connected by a second metallic line. The first metallic lines are connected to the second metallic lines through first vias. The second metallic lines are connected to touch electrodes through second vias. The second metallic lines function as bridges between the touch electrodes and first metallic lines. Using the first metallic lines to transmit touch signal avoids having the touch signal transmission lines configured in a same metallic layer as the data lines, and prevents the metallic layer from having too high a density and limiting the dimension of the pixels, thereby enhancing the aperture ratio and power consumption.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a structural schematic diagram of an array substrate according to an embodiment of the present invention.

FIG. 2 is a structural schematic diagram of the array substrate of FIG. 1 without second metallic layer.

FIG. 3 is a sectional diagram showing a section of the A area of FIG. 1 along a first direction.

FIG. 4 is a structural schematic diagram of a display device according to an embodiment of the present invention.

### DETAILED DESCRIPTION OF PREFERRED EMBODIMENTS

The following descriptions for the respective embodiments are specific embodiments capable of being implemented for illustrations of the present invention with referring to appended figures.

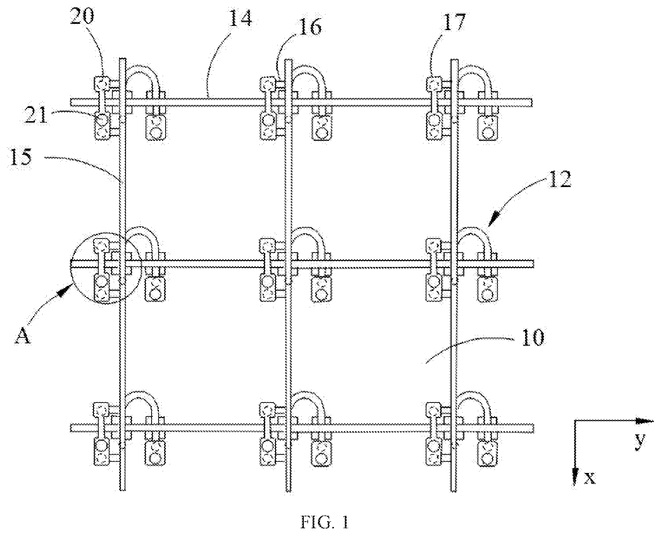

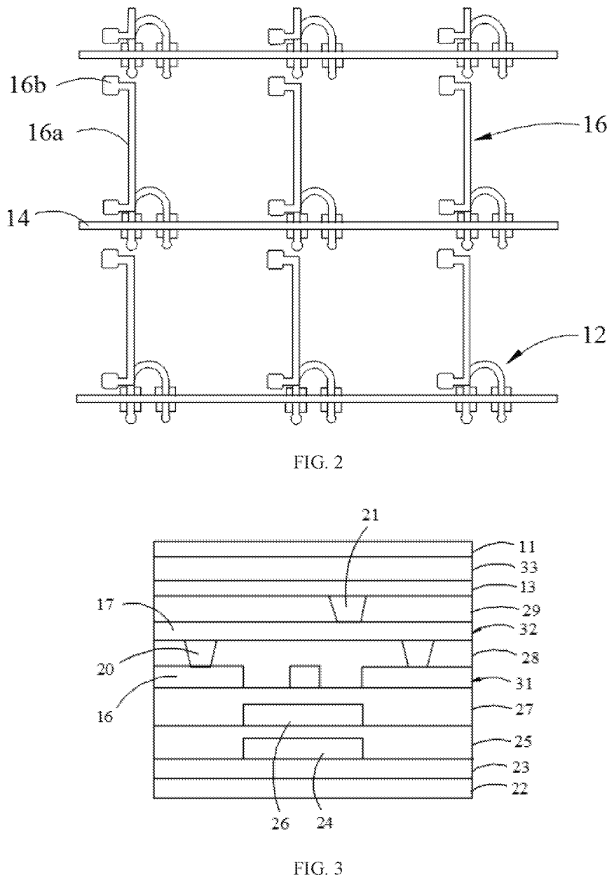

Please referring to FIGS. 1 to 3. FIG. 1 is a structural schematic diagram of an array substrate according to an embodiment of the present invention but omitting non-conducting film layer, pixel electrodes, and touch electrodes. FIG. 2 is a structural schematic diagram of the array substrate of FIG. 1 without second metallic layer. FIG. 3 is a sectional diagram showing a section of the A area of FIG. 1 along a first direction.

An array substrate 1 according to an embodiment of the present invention includes multiple pixel units 10 arranged in an array, each including a pixel electrode 11 (see FIG. 3), a thin film transistor (TFT) 12, a touch electrode 13 (see FIG. 3), a scan line 14, and a data line 15. The scan line 14 is configured along a first direction and the data line is configured along a second direction. The scan lines 14 and data lines 15 of the array substrate 1 cross each other. The pixel electrodes 11 are connected to the scan lines 14 and the data lines 15 through the TFTs 12. Each pixel unit 10 also includes first metallic line 16 configured along the first direction and second metallic line 17 configured along the second direction. The first metallic lines 16 are disposed in a same layer as the scan lines 14. The second metallic lines 17 are disposed in a same layer as the data lines 15. Two neighboring first metallic lines 16 along the first direction are connected by a second metallic line 17. The first metallic lines 16 are connected to the second metallic lines 17 through first vias 20. The second metallic lines 17 are connected to touch electrodes 13 through second vias 21.

The first direction is the direction of the X-axis and the second direction is the Y-axis direction shown in FIG. 1. The first and second directions are perpendicular. The multiple scan lines 14 along the first direction and the multiple data lines 15 along the second direction cross each other to form a grid, thereby defining multiple pixel units 10 arranged in an array. Each pixel unit 10 is located in a cell of the grid. The array substrate 1 includes display area and non-display area. The TFTs 12 are located within the non-display area of the array substrate 1. The pixel electrodes 11 and touch electrodes 13 of the present embodiment are transparent electrodes.

Each touch electrode 13 is for receiving touch signal and transmits the touch signal to a second metallic line 17 through a second via 21. The second metallic line 17 in turn transmits the touch signal to first metallic lines 16 through first vias 20. The second metallic line 17 functions as a bridge between the touch electrode 13 and first metallic lines 16. Using the first metallic lines 16 to transmit touch signal avoids having the touch signal transmission lines configured in a same metallic layer as the data lines 15, and prevents the metallic layer from having too high a density and limiting the dimension of the pixels, thereby enhancing the aperture ratio and power consumption.

Preferably, the data lines 15 cover sections of the first metallic lines 16 along the first direction. In other words, projections of the data lines 15 to the plane where the first metallic lines 16 are located overlap with sections of the first metallic lines 16 along the X axis. As such, the first metallic lines 16 do not affect the dimension of the array substrate 1's pixels, thereby further enhancing the aperture ratio and power consumption.

Specifically, each first metallic line 16 includes a vertical section 16a along the first direction and lateral sections 16b extended from two ends of the vertical section 16a along the second direction. The data lines 15 cover the vertical sections 16a. That is, projections of the data lines 15 to the plane where the first metallic lines 16 are located overlap with the vertical sections 16a. The lateral sections 16b are connected to the second metallic lines 17 through the first vias 20. The second metallic lines 17 connect two neighboring first metallic lines 16 along the first direction together through the first vias 20.

The lateral sections 16b are parallel to the scan lines 14, The second metallic lines 17 are parallel to the data lines 15. The second metallic lines 17 cross the scan lines 14. The second metallic lines 17 and the pixel electrodes 11 are located at the laterals sides of the data lines 15, respectively. The second metallic lines 17 are disposed in the display area of the array substrate 1.

In present embodiment, the TFTs 12 are top-gated TFTs. Specifically, each pixel unit 10 includes a substrate 22, a first buffer layer 23, a shading layer 24, a second buffer layer 25, a poly-silicon (poly-Si) layer 26, a gate insulation layer 27, a first metallic layer 31, a first interlayer dielectric (ILD) layer 28, a second metallic layer 32, a second ILD layer 29, a touch electrode 13, a third ILD layer 33, and a pixel electrode 11.

The first buffer layer 23 is disposed on the substrate 22. The shading layer 24 is disposed on the first buffer layer 23. The second buffer layer 25 is disposed on the first buffer layer 23 covering the shading layer 24. The poly-Si layer 26 is disposed on the second buffer layer 25. The gate insulation layer 27 is dispose on the second buffer layer 25 covering the poly-Si layer 26. The first metallic layer 31 is disposed on the gate insulation layer 27 for forming the first metallic lines 16 and scan lines 14. The scan lines 14 functions as gate electrodes for the TFTs 12. The first ILD layer 28 covers the first metallic layer 31. The second metallic layer 32 is disposed on the first HI) layer 28 for forming the second metallic lines 17 and data lines 15. The second ILD layer 29 covers the second metallic layer 32. The touch electrode 13 is disposed on the second ILD layer 29. The third ILD layer 31 covers the touch electrode 13. The pixel electrode 11 is disposed on the third ILD layer 31. The source electrodes of the TFTs 12 are connected to the data lines 15. The drain electrodes of the TFTs are connected to the pixel electrodes 11.

The present invention also teaches a display device, which may be liquid crystal display (LCD) or an organic light emitting diode (OLED) display. The present invention does to provide specific limitation.

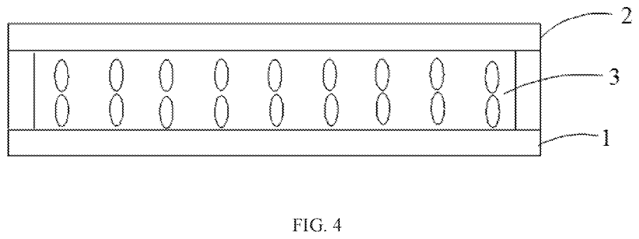

As shown in FIG. 4, the display device is a LCD and includes an array substrate 1 as described above, color filter (CF) substrate 2, and a liquid crystal layer 3. The array substrate 1 and the CF substrate 2 are disposed oppositely. The liquid crystal layer 3 is sandwiched between the array substrate 1 and the liquid crystal layer 2. The display device has enhanced aperture ratio and power consumption through the adoption of the above described array substrate 1.

Above are embodiments of the present invention, which does not limit the scope of the present invention. Any equivalent amendments within the spirit and principles of the embodiment described above should be covered by the protected scope of the invention.

What is claimed is:

1. An array substrate, comprising a plurality of pixel units arranged in an array, wherein each pixel unit comprises a pixel electrode, a thin film transistor (TFT), a touch electrode, a scan line, and a data line; the scan lines are configured along a first direction; the data lines are configured along a second direction; the scan lines and data lines cross each other; the pixel electrodes are connected to the scan lines and the data lines through the TFTs 12; each pixel unit further comprises a first metallic line configured along the first direction and a second metallic line configured along the second direction; the first metallic lines are disposed in a same layer as the scan lines; the second metallic lines are disposed in a same layer as the data lines; two neighboring first metallic lines along the first direction are connected by a second metallic line; the first metallic lines are connected to the second metallic lines through first vias; and the second metallic lines are connected to touch electrodes through second vias.

2. The array substrate according to claim 1, wherein the data lines cover sections of the first metallic lines along the first direction.

3. The array substrate according to claim 2, wherein each first metallic line comprises a vertical section along the first direction and lateral sections extended from two ends of the vertical section along the second direction; the data lines cover the vertical sections; and the lateral sections are connected to the second metallic lines through the first vias.

4. The array substrate according to claim 3, wherein the lateral sections are parallel to the scan lines.

5. The array substrate according to claim 1, wherein the second metallic lines are parallel to the data lines.

6. The array substrate according to claim 1, wherein the second metallic lines and the pixel electrodes are respectively disposed to the laterals sides of the data lines.

7. The array substrate according to claim 6, wherein the second metallic lines are disposed in a display area of the array substrate.

8. The array substrate according to claim 1, wherein the TFTs are top-gated TFTs.

9. The array substrate according to claim 7, wherein each pixel unit comprises a substrate; a first buffer layer, a shading layer; a second buffer layer, a poly-silicon (poly-Si) layer, a gate insulation layer, a first metallic layer, a first interlayer dielectric (ILD) layer, a second metallic layer, a second ILD layer, a touch electrode, a third ILD layer, and a pixel electrode; the first metallic layer is for forming the first metallic lines and scan lines; and the second metallic layer is for forming the second metallic lines and data lines.

10. A display device comprising an array substrate, wherein the array substrate comprises a plurality of pixel units arranged in an array; each pixel unit comprises a pixel electrode, a thin film transistor (TFT), a touch electrode, a scan line, and a data line; the scan lines are configured along a first direction; the data lines are configured along a second direction; the scan lines and data lines cross each other; the pixel electrodes are connected to the scan lines and the data lines through the TFTs 12; each pixel unit further comprises a first metallic line configured along the first direction and a second metallic line configured along the second direction; the first metallic lines are disposed in a same layer as the scan lines; the second metallic lines are disposed in a same layer as the data lines; two neighboring first metallic lines along the first direction are connected by a second metallic line; the first metallic lines are connected to the second metallic lines through first vias; and the second metallic lines are connected to touch electrodes through second vias.

11. The display device according to claim 10; wherein the data lines cover sections of the first metallic lines along the first direction.

12. The display device according to claim 10, wherein each first metallic line comprises a vertical section along the first direction and lateral sections extended from two ends of the vertical section along the second direction; the data lines cover the vertical sections; and the lateral sections are connected to the second metallic lines through the first vias.

13. The display device according to claim 12, wherein the lateral sections are parallel to the scan lines.

14. The display device according to claim 10, wherein the second metallic lines are parallel to the data lines.

15. The display device according to claim 10, wherein the second metallic lines and the pixel electrodes are respectively disposed to the laterals sides of the data lines.

16. The display device according to claim 15, wherein the second metallic lines are disposed in a display area of the array substrate.

17. The display device according to claim 10, wherein the TFTs are top-gated TRTs.

18. The display device according to claim 16, wherein each pixel unit comprises a substrate, a first buffer layer, a shading layer, a second buffer layer, a poly-silicon (poly-Si) layer, a gate insulation layer, a first metallic layer, a first interlayer dielectric (ILD) layer, a second metallic layer, a second ILD layer, a touch electrode, a third ILD layer, and a pixel electrode; the first metallic layer is for forming the first metallic lines and scan lines; and the second metallic layer is for forming the second metallic lines and data lines.
